(19) United States
(12) Patent Application Publication
(10) Pub. No.: US 2008/0318168 A1
(43) Pub. Date: Dec. 25, 2008

(54) Method and Device for Structuring a Substrate

(76) Inventors: Krysztof Szot, Julich (DE); Frank Peter, Dresden (DE); Bernd Reichenberg, Aachen (DE)

Correspondence Address: K.F. ROSS P.C., 5683 RIVERDALE AVENUE, SUITE 203 BOX 900, BRONX, NY, 10471-0900, US

(21) Appl. No.: 11/662,308

(22) PCT Filed: Jul. 27, 2005
(86) PCT No.: PCT/DE05/01321

§ 371 Date: Mar. 8, 2007

(30) Foreign Application Priority Data
Sep. 9, 2004 (DE) 10 2004 044 083.2

(51) Int. Cl. G03F 7/20; G03B 27/42

(52) U.S. Cl. 430/322; 355/53

(57) ABSTRACT

The invention relates to a method for structuring a substrate. According to said method, at least one mask with at least one opening is arranged over the substrate, and unmasked regions are modified in relation to masked regions of the substrate in order to form structures. The inventive method is characterised in that the representation of the mask opening on and/or in the substrate has smaller dimensions than those of the actual mask opening. The invention also relates to a device for carrying out said method.

The invention relates to a method and an apparatus for structuring a substrate.

An important step in the production of semiconductor components is the structuring of a substrate. The substrate is marked with regions that are subsequently removed, for example by etching, or metallized. Through a plurality of consecutive process steps, the basic elements of passive and active components are produced.

In industrial applications, optical lithography is used for this purpose. Lithography serves to transfer design patterns of an integrated component onto semiconductor wafers using various radiation methods, either directly or indirectly using masks, also the methods for producing the masks being considered part of lithography.

The starting point of all lithography processes is the design of a component available in data form on a storage media. This design must be transferred as a geometric pattern onto a carrier material, a substrate or a layer provided on a substrate. In the case of indirect lithography methods, the required number of master masks is produced this way, while in the case of direct methods the pattern is applied directly on the wafer, using the necessary number of passes for achieving the complexity of the element resulting from the design. Previously, a radiation-sensitive layer, the photoresist, is applied to the material to be exposed to light, which layer undergoes a change as a result of the radiation applied to the exposed regions. As a result, selective removal of the exposed (positive method) or unexposed regions (negative method) becomes possible. The remaining layer is intended to the protect the material beneath from the effects of the subsequent process steps. While during mask production the only important aspect is the production of radiation-permeable and/or absorbing regions, the true functional elements such as traces, diodes or transistors are engraved in the wafers as substrates through chemical processes, such as vapor deposition, epitaxy, implantation, deposition, and the wafers thus become structured.

In the case of indirect lithography methods, the semiconductor material is exposed while interposing the masks, various types of radiation being used. At present the most common method is photolithography, also referred to as optical lithography.

Masks are used for transferring the structures onto or into the semiconductor substrates (wafers). First, the number of masks required is produced. The patterns of the masks are then transferred consecutively onto the substrate, which prior to this step was sensitized by coating it with photoresist. After each exposure and after removing the photoresist in the exposed or unexposed regions, depending on the method, the substrate undergoes processes that provide it with the electronic properties determined by the design.

The masks serving as carriers of geometric information are typically made of a glass substrate having a chromium or chromium-oxide layer about 100 nm thick, which is removed by wet or dry etching in certain regions to produce the desired pattern. The transfer of the pattern onto the semiconductor material is uniformly referred to as exposure with all types of radiation that are used.

The masks used with mask lithography methods contain the structures in a scale of 1:1. In addition to projection methods, contact printing is available, in which the mask is pressed onto the wafer with the pattern side, and also proximity printing, in which a distance of about 10 to 20 micrometers between the mask and wafer is used.

Shadow masks are also used for other structuring methods, such as the implantation of ions or the deposition of metals, for example, in or on the substrate.

For special applications, such as for the production of masks as well as in research and development, shorter-wave and more energy-rich rays, such as X-rays (x-ray lithography), electron beams and ion beams (ion-beam lithography) are used, which allow higher lateral resolution and consequently greater integration density of the elements.

Extreme ultraviolet lithography having a radiation wavelength of about 11-14 nanometers, x-ray lithography (radiation smaller than 10 nanometers) and the electron-beam writing method, where the structure is written directly into the resist on a substrate using an electron beam and no mask is required, are mentioned by way of example.

Ion-beam lithography is comparable to electron-beam lithography, with an ion beam being used instead of electrons at first for writing on the substrate.

In the case of the nanoimprint method, a punch having fine structures is pressed into a resist. The resist is cured, and the punch is retracted.

Also known is the Dip Pen Nanolithography™ (DPN™) technique. This technique uses a method according to which molecular “ink” is used to write on a substrate for producing minute nanostructures. The molecules are applied on the substrate using a modified scanning probe microscope.

The disadvantage with the above methods is that they are associated with weaknesses in the production of the nanostructures.

In the case of optical lithography, the minimum structural size that can be produced is limited by the wavelength. The lenses and reflectors used with extreme ultraviolet lithography are very expensive to manufacture and the production quality of the optical components that can be achieved is limited.

The electron-beam writing technique uses a serial writing process to achieve high resolutions in the range of around 10 nanometers, which appears too slow for industrial applications. The same applies to ion-beam lithography. The backscattering of ions, which is dependent on the structure, is also a disadvantage. The nanoimprint method on the other hand is limited by the time required for the resist to cure. The output achieved for the structuring of semiconductor elements is therefore limited. So far, this method has also only be used on flat, but not on textured surfaces. So as to produce semiconductors, structuring on an existing texture is required.

It is therefore disadvantageous that each of the methods referred to above is limited either by the mask structure or the complexity required for overcoming the minimal structures in the mask.

It is therefore the object of the invention to provide a method that allows the production of structures smaller than 50 nanometers, for example, and that is not associated with the disadvantages according to the state of the art mentioned above.

The object is achieved with a method according to the main claim and an apparatus according to the dependent claim. Advantageous embodiments will be apparent from the claims referring to these two claims.

The method for structuring a substrate provides that at least one mask with an opening is positioned above the substrate. Because of the one mask, unmasked regions are changed during the process compared to masked regions of the substrates and form structures. It is possible to structure and/or change a layer provided on the substrate instead of a substrate.

The method for structuring a substrate provides that at least one mask with an opening is positioned above the substrate and that unmasked regions are changed compared to masked regions of the substrates to form structures. It is therefore characterized in that during the structuring process measures are taken that result in a reproduction of the mask opening on and/or in the substrate, which opening is smaller in size than the actual size of the mask opening.

As a result, advantageously smaller structures than before are formed and produced on or in the substrate. Existing structures have been defined by the dimensions of the mask opening. As a result, this method advantageously overcomes the existing limited minimum structure, which is dependent on the production of the mask or the method used.

The geometry of the structure in the substrate may advantageously be produced as a function of the selected geometry of the sequence of relative movements between the substrate and mask opening(s).

At least two masks with openings may be positioned axially, meaning in the z-direction, above each other above a substrate. Again in the z-direction above the masks, the structuring sources may be provided, for example implantation, deposition and illumination sources.

By way of example, two identical masks having identical shaped mask openings may be positioned in the z-direction above the substrate. Provided that in their projection the openings of the masks are offset slightly from and in a defined manner to each other in the X- and/or Y-directions, defined images are produced in the substrate, which are defined by the amount of overlap of the mask openings. When using a suitable structuring method, for example a deposition method, smaller structures are produced than are defined by the actual mask openings.

A plurality of identical mask openings may be provided in the masks offset from each other in the X- and/or Y-directions. This advantageously ensures that a plurality of identical structures are produced in a simple manner in or on the substrate, which structures are smaller than the mask openings. The structures and/or regions have defined dimensions as a function of the overlap of the mask openings.

As a function of the result to be achieved, it is of course also possible to use more than two masks and to position them in the z-direction axially one above the other as well as offset from each other in the X- and/or Y-directions. During the structuring process, the masks are positioned above the substrate in a stationary manner.

In a particularly advantageous embodiment of the invention, however, at least one mask is moved during the process relative to the substrate such that the mask opening is not reproduced true to scale, but instead smaller. This image, depending on the geometry of the sequence of movements of the mask, may have a different shape than the mask opening. The object of the invention is also achieved through this measure alone, and a structure is produced on the substrate that is smaller than that defined by the actual dimension of the mask opening.

During this process, for example a deposition, implantation or light exposure step may be performed for structuring purposes, or also a combination of these steps may be carried out to produce minute structures. A deposition technique is used, for example, to produce metallization and insulating layers. Implantation may be used to subject nanoregions to p- and n-doping, and by exposing the substrate to light, for example the photoresist is subjected to exposure.

Depending on the processes, this way minute structures are formed by positioning and/or moving the mask(s) above the substrate in relative terms, which structures cannot be achieved with methods according to the state of the art since they only provide a single, stationary mask above the substrate.

To the extent that during the process at least one mask is moved above the substrate, the structure can be produced as a function of the geometry of the sequence of movements of the mask. A rectangular movement of a round or square mask opening produces a corresponding rectangular structure in or on the substrate as a result of the structuring, such as deposition or implantation, during the movement. Circular or elliptic movements may result in corresponding shapes of the structure in or on the substrate. Each time structures are produced that are smaller than the actual mask opening.

When using light exposure for structuring, the mask may have a glass support with a metal layer, comprising chromium for example, applied thereon, which is used, for example, for UV-radiation lithography.

It is also possible to select a mask comprised of magnetic material. Masks of this type can be moved by means of magnets, or they are positioned in a stationary manner above a microscope slide comprising such a magnet.

The method may be carried out discontinuously, for example the deposition, implantation or exposure or also any other structuring process may be suspended temporarily during the relative movement. It is also possible, however, to carry out the relative movement of the mask(s) to the substrate discontinuously during a continuously progressing structuring step. It is also possible to carry out both processes, meaning the movement and the structuring process (such as the deposition) discontinuously using diaphragms.

For example, two masks may be positioned axially, meaning in the z-direction, one above the other on the substrate, the overlapping regions of these masks in their projection achieve a smaller reproduction of the openings on the substrate due to an offset in the X- and/or Y-directions. During structuring, for example during deposition, the offset is temporarily suspended and both masks are moved similarly relative to the substrate toward a position. Then another deposition is carried out.

This has the advantageous effect that regions or surfaces structured diffusely during the movement and sporadically on/in the substrate are reduced or even completely avoided.

Alternatively, at least one mask may remain stationary and the substrate may be moved.

By moving the mask(s) in a certain geometric sequence relative to the substrate and through suitable continuous or discontinuous structuring, for example as a result of discontinuous exposure or deposition or also the discontinuous movement of at least one mask relative to the substrate, every time structures are produced on or in the substrate, which structures are smaller than the actual mask opening(s) and optionally have defined different shapes than the opening(s).

Accordingly, a plurality of, particularly two or four, masks may be moved relative to the substrate during the process. The masks with openings may move relative to other masks, but do not have to, in order to produce minute structures during structuring, for example a deposition in or on the substrate.

An apparatus according to the invention for structuring a substrate or a layer applied on a substrate comprises means according to the invention for performing relative movements between at least one mask having at least one mask opening and the substrate.

An apparatus according to the invention for carrying out the method, however, may also comprise at least two masks with mask openings, which masks are positioned one above the other in the z-direction, the mask openings of which masks are offset from each other in the X- and/or Y-directions. This way, at least the two masks and the structuring source, for example a deposition source, are positioned in the z-direction above the substrate.

In a particularly advantageous embodiment of the invention, the apparatus comprises at least one piezoelectric element/piezoelectric actuator as the means for moving the mask(s). The apparatus can perform the relative movement by means of an inertial drive mechanism.

In the apparatus, at least one mask may be provided on a microscope slide. The microscope slide is configured such that it carries the mask at the edges thereof, for example. For this purpose, the microscope slide is likewise provided with an opening that is larger than the opening of the carried mask such that the deposited or implanted material or light can pass through the mask opening and the opening of the microscope slide during structuring.

The structure is produced by deposition, implantation or exposure of a material on or in an unmasked region of the substrate.

The piezoelectric element or elements may be positioned laterally on the mask or masks.

The information about the relative position of the masks to the substrate may be transmitted by means of optical, interferometric and/or capacitive sensors.

The piezoelectric element or elements move the mask(s) above the substrate. It is possible to provide the mask directly on the piezoelectric elements and move it with them. In this case, the microscope slide can be eliminated. For this purpose, the mask may be moved using at least one piezoelectric element that is glued to the mask.

It is also possible to move the substrate using at least one piezoelectric element. It is furthermore possible to move a substrate that is provided on a microscope slide toward the mask or masks using at least one piezoelectric element.

This way, relative movement can be performed between the substrate and at least one mask.

It is particularly advantageous if the apparatus has a microscope slide comprising a magnet or a vacuum apparatus for the mask. Provided that the mask comprises magnetic material, it can be held and moved safely using the microscope slide.

The apparatus advantageously comprises at least three piezoelectric elements for each object to be moved. This allows three-point seating of the object to be moved. The object to be moved is the microscope slide, the mask(s) or the substrate.

The apparatus may comprise a nanomanipulator. The moving means are part of the nanomanipulator.

It is particularly advantageous if the apparatus comprises a control unit for the consecutive relative movements of the mask toward the substrate, for example a computer.

The apparatus is able to carry out discontinuous sequences of movements and/or structuring steps.

For this purpose, the apparatus advantageously comprises shutter arrangements for discontinuous structuring. The shutter arrangement is inserted between the mask(s) and, for example, a deposition source as the structuring source. The shutter arrangement then interrupts a deposition as the structuring process.

In connection with a diode arrangement provided beneath the mask openings it is possible to control clogging of the masks by means of a UV beam that is directed at the mask openings. This way, corrections can be made to the apparatus in a timely manner, before the deposition results in decreased mask openings. It is possible to control the change of the mask opening surface.

The invention will be explained in more detail hereinafter with reference to illustrated embodiments and the attached figures.

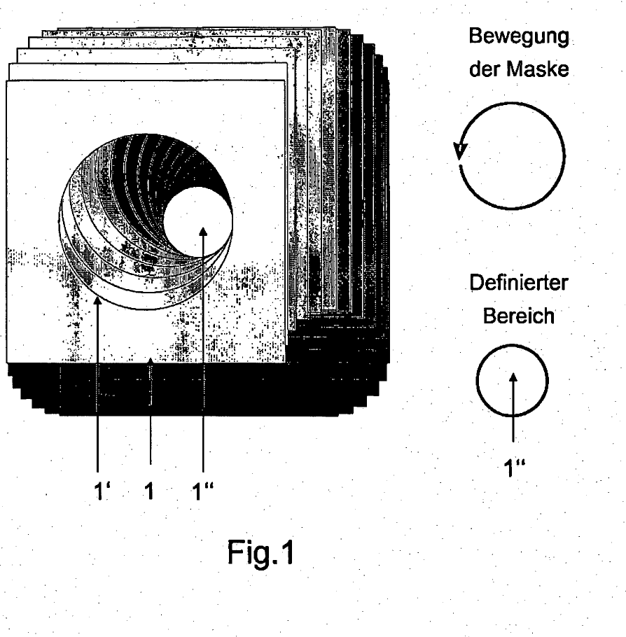

FIGS. 1 to 4 show top views of the sequence of movements of a square mask 1, 21, 31 and 41 for structuring a substrate that is not shown. The sequence of movements of the masks is reflected by the changes in the mask shading from black to light gray. The starting and ending positions of the mask in or on the substrate are identical for the creation of the defined region and the formation of the structure.

FIG. 1 shows a mask 1 with a circular mask opening 1′. The mask performs a substantially circular movement in 21 steps between the starting and ending positions.

Through continuous deposition of the mask moving above a substrate, a circular region 1″ is defined on the inside of the mask opening 1′, which region is subject to permanent deposition during the movements of the mask. This region 1″ is reproduced on the substrate. In the defined region 1″, the substrate has a different structure than in the regions covered with the mask 1. The surface of the mask opening 1′ is, for example 1963 mm² with a radius of 25 mm. The defined, reproduced region 1″ has a surface of 314 mm² with a radius of 10 mm. The reproduced region 1″ therefore has a surface that is about 84% smaller than the mask opening 1″. Continuous deposition results in diffusely defined regions at the edges of the defined region, on which there is only limited deposition.

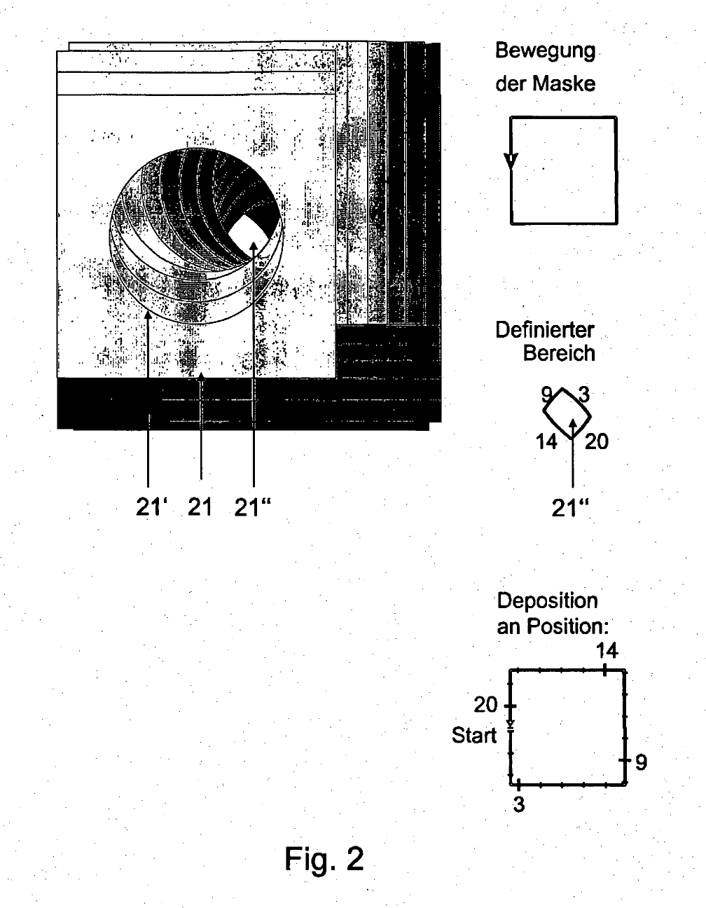

FIG. 2 shows a mask 21 with a circular mask opening 21′. The mask performs a square movement in 21 steps between starting and ending positions.

By means of discontinuous deposition only in positions 3, 9, 14 and 20 of the mask moving above the substrate, a substantially square region 21″, illustrated with a light color, is defined on the inside of the mask opening 21′, in which material is deposited four times. The geometry of the region 21″ is accordingly defined in only four individual steps. The steps between do not contribute to defining the region 21″. In the defined region, the substrate has a different structure than in the regions covered with the mask 1.

The surface of the mask opening 21′ is, for example 1963 mm² with a radius of 25 mm. The defined, reproduced region 21″ has a surface of 92.7 mm². The reproduced region 21″ therefore has a surface that is about 95% smaller than the mask opening 21′.

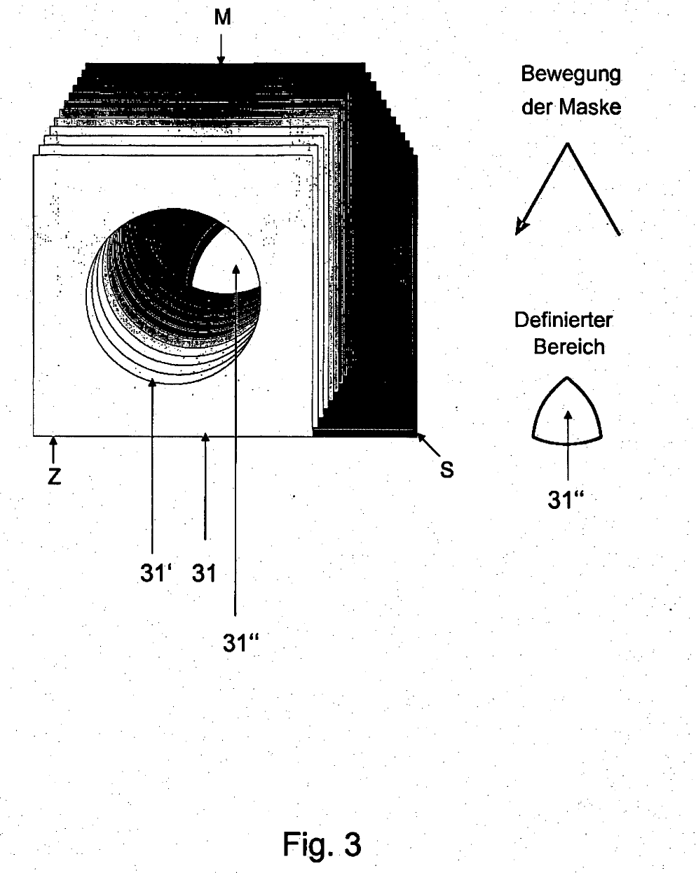

FIG. 3 shows a mask 31 with a circular mask opening 31′. The mask performs movements along an isosceles triangle, as that illustrated according to FIG. 3 on the top right, in 23 steps.

Through continuous or discontinuous deposition on the mask 31 moving above the substrate, a triangular region 31″ is defined on the inside of the mask opening 31′. This region 31″ is reproduced on the substrate. In the defined region, the substrate has a different structure than in the regions covered with the mask 31.

The surface of the mask opening 31′ is, for example 1963 mm² with a radius of 25 mm. The defined, reproduced region 31″ has a surface of 180 mm². The reproduced region 31″ therefore has a surface that is about 91% smaller than the mask opening 31′.

Continuous deposition results in diffusely defined regions at the edges of the defined region 31″, on which only some deposition took place.

The discontinuous deposition at the starting, center and ending positions (S, M, Z), which correspond to the positions 1, 12 and 23, however, produces the defined region 31″ with only three positions. The steps between do not contribute to defining the region 31″.

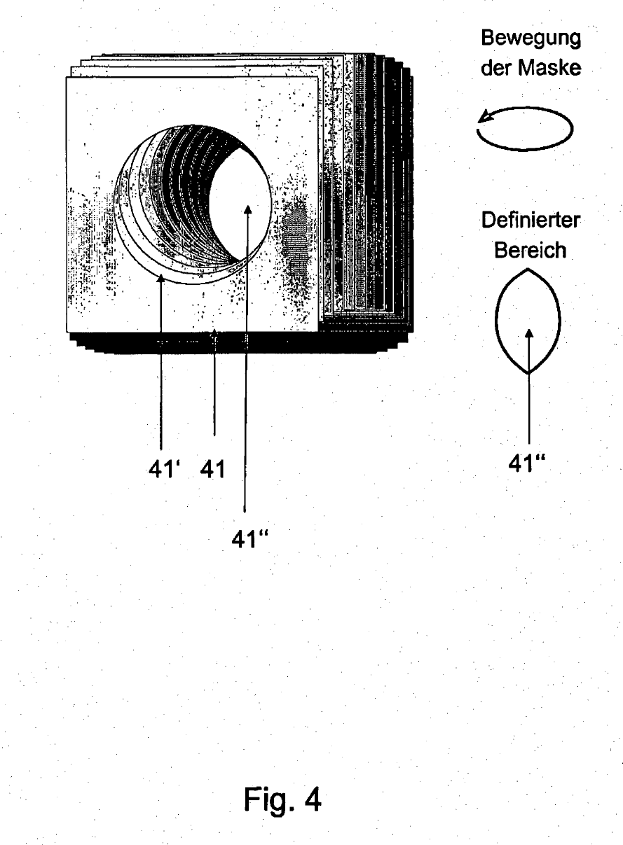

FIG. 4 shows a mask 41 with a circular opening 41′. The mask performs a horizontal elliptic movement in 23 steps, of which only the last 22 are illustrated.

Through the continuous deposition of the mask 41 moving elliptically above the substrate, a vertically elliptic region 41″ is defined on the inside of the mask opening 41′. This region 41″ is reproduced on the substrate. In the defined region 41″, the substrate has a different structure than in the regions covered with the mask 41.

The surface of the mask opening 41′ is, for example 1963 mm² with a radius of about 25 mm. The defined, ellipsoid region 41″ has a surface of about 607 mm². The region 41″ therefore has a surface that is about 69% smaller than the mask opening 41′.

Continuous deposition again results in a diffusely defined region outside the defined region 41″.

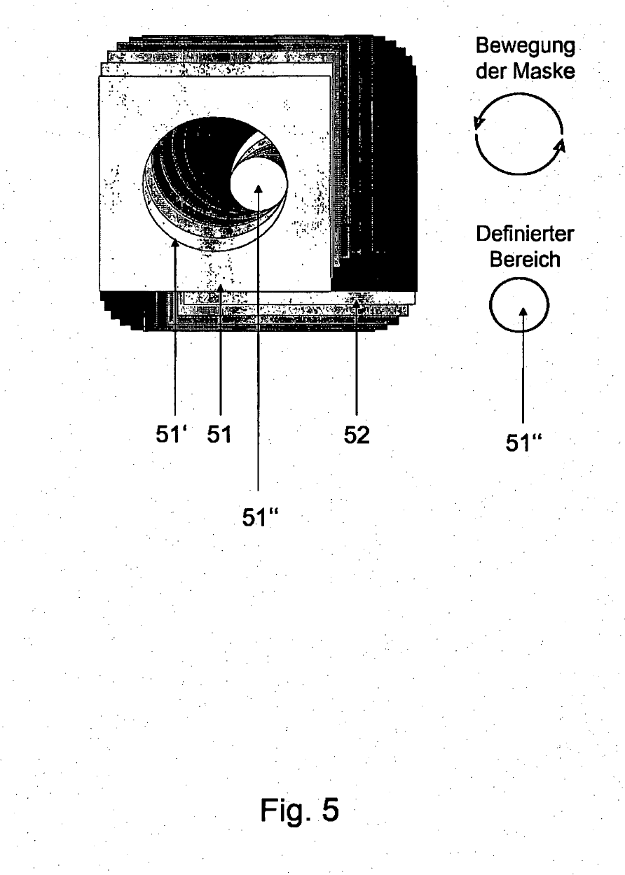

FIG. 5 shows a top view onto the sequence of movements of two square masks 51 and 52 that are positioned one above the other for structuring a substrate that is hot shown. The sequence of movement of each mask is reflected by the changes in the mask shading from black to light gray. For the creation of the defined region 51″ and formation of the structure in or on a substrate, the ending position of the mask 52 is identical with the starting position of the mask 51, and vice versa. The masks perform at least semicircular movements with a total of 12 positions in order to define and reproduce a circular region 51″ on or in the substrate.

As a result of the continuous deposition of the masks 51, 52 moving in a circular fashion above the substrate, the circular region 51″ on the inside of the mask opening 51′ and 52′ is defined and reproduced. Due to the way the figures are represented, the mask opening 52′ is not shown completely. The region 51″ is reproduced on the substrate. In the defined region 51″, the substrate has a different structure than in the regions covered with the masks 51 and 52. Similar to the embodiment according to FIG. 1, the defined, reproduced region 51″ has a surface that is about 84% less than the respective mask opening 51′ and 52′. Continuous deposition results in a diffusely defined region at the edges of the defined region 51″, which advantageously is much smaller than in FIG. 1.

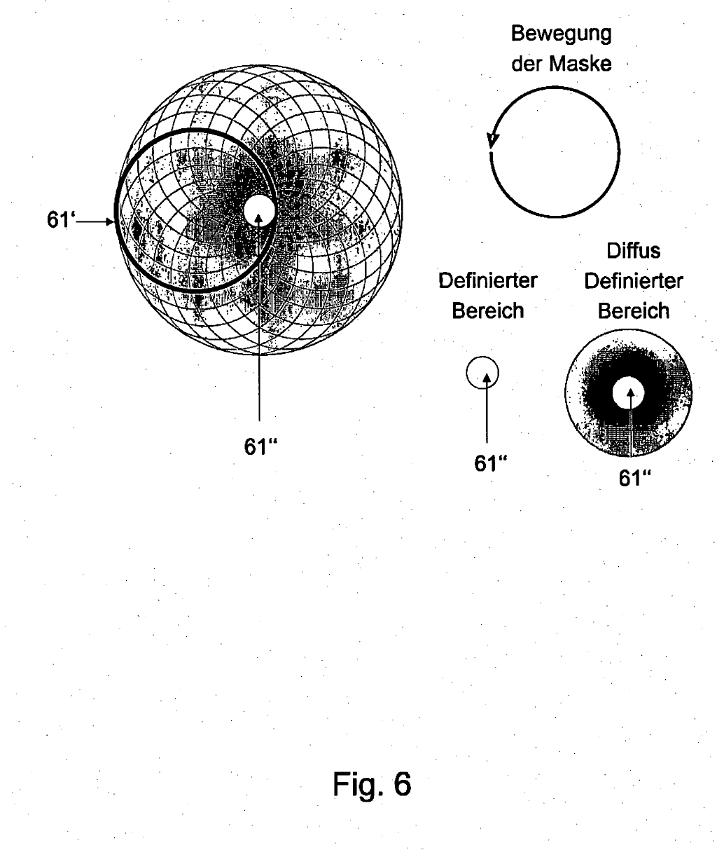

Diffusely defined regions of the substrates like this produced with continuous deposition and/or structuring are placed on gray backgrounds for the different mask arrangements according to FIGS. 6 to 8.

FIGS. 6 to 8 show top views of the sequence of movements; and the positions of the mask openings 61′, 71′, 72′, 81′, 82′, 83′ and 84′ based on the thin circles. Unlike in FIGS. 1 to 5, the solid region of the mask is not shown. Bold circles indicate the starting or ending positions of the mask openings 61′, 71′, 72′, 81′, 82′, 83′ and 84′.

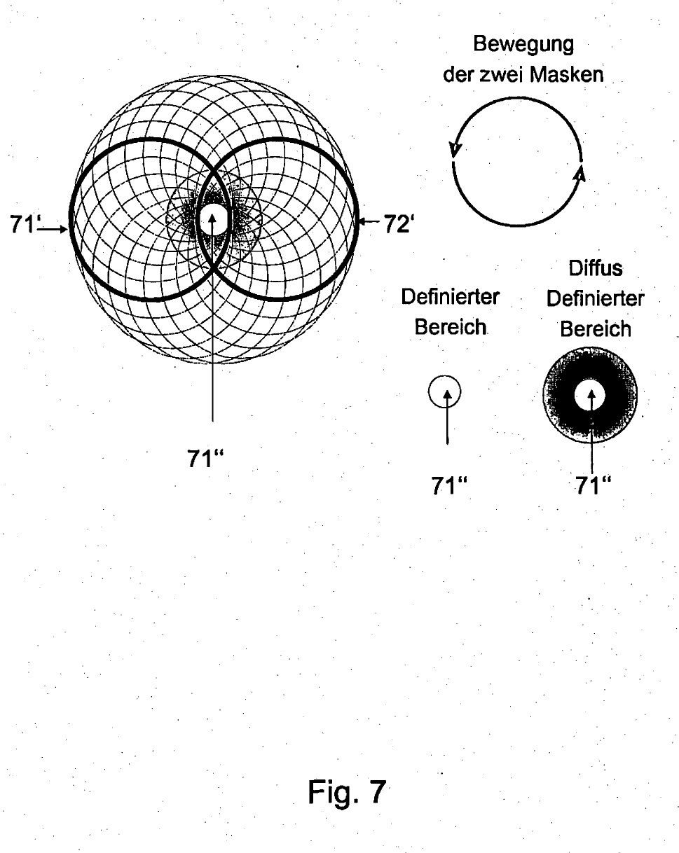

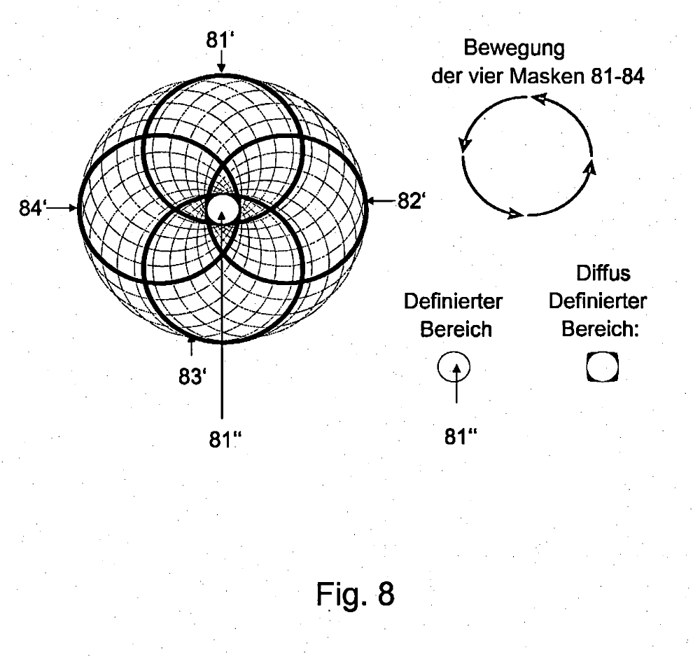

Each mask alone and/or in combination with the remaining masks (FIGS. 7 and 8) performs circular movements in order to produce a circular, defined region as a reproduction in or on the substrate. It is conceivable to run other sequences of movements with different geometric patterns in order to arrive at different structures on or in the substrate, see FIGS. 1 to 4.

FIG. 6 shows the sequence of movements of a mask opening 61′ similar to that of the mask opening 1′ according to FIG. 1. FIG. 7 illustrates the sequence of movements of the mask openings 71′ and 72′ similar to that of the mask openings 51′ and 52′ from FIG. 5.

In FIG. 6, the starting and the ending positions of the mask are identical for the creation of a defined, circular region 61″ and the formation of the structure in or on the substrate. The circular mask opening 61′ is moved above a substrate (not shown) that is placed in the image plane behind the opening 61′ in 21 steps, illustrated by the thin circles.

A deposition source may be provided in the image plane in front of the mask. The continuous deposition of the mask performing circular movements above the substrate defines a circular region 61″ on the inside of the mask opening 61′ via the opening 61′, which region is smaller than the surface of the opening 61′ of the mask. This region 61″ is reproduced on the substrate. In the defined region 61″, the substrate has a different structure than in the diffuse region covered partially with the mask. In order words, the defined region 61″ is permanently structured by the mask performing circular movements, while the region surrounding the defined region 61″ is covered in part by the mask, also as a function of the position and is subject to fewer changes because only partial depositions occur thereon.

The defined, reproduced region 61″ therefore has a surface that is about 96% smaller than the mask opening 61′. Continuous deposition results in the diffusely defined region placed on gray background in the surrounding area of the defined region 61″, which is produced by the deposited overall surface of the mask opening 61′ performing circular movements above the substrate. Due to space constraints, the diffusely defined gray region on the bottom right in FIG. 6, however, is not illustrated in the same scale as the remaining parts of the figure.

Similar to FIG. 5, in FIG. 7 the ending position of the mask opening 71′ is identical to the starting position of the mask opening 721 for the creation of the defined region 71″ and the formation of the circular structure in or on a substrate. The same applies to the ending position of mask opening 72′ in relation to the starting position of mask opening 71′. The masks 71 and 72 perform semicircular movements with a total of 12 positions, including the starting and ending positions, in order to define a circular region 71″, which is reproduced on the substrate. After reaching the ending position, the sequence of movements of each mask opening 71′, 72′ may be continued to perform a complete circular movement or it may return to the respective starting position. In the latter case, both masks only perform semicircular back and forth movements, which together with the other mask form the circular, defined region 71″. In the first case, both masks already perform circular movements themselves. The two masks 71, 72 are moved above a substrate (not shown) that is placed in the image plane behind the opening 71′ and 72′.

A deposition source may be provided in the image plane in front of the masks 71, 72. Continuous deposition of the masks moving in a circular fashion above the substrate defines the circular region 71″ on the inside of the mask openings 71″, 72′ via the openings 71′ and 72′. According to the invention, this region is much smaller than the respective actual surfaces of the openings 71′, 72′ of the masks. This region 71″ is reproduced on the substrate. In the defined region 71″, the substrate has a different structure than in the diffuse region covered partially with the masks, which region is again placed on a gray background. In other words, the defined region 71″ is subject to permanent deposition by the mask performing (semi-)circular movements, while the region surrounding the defined region 71″ is covered in part by the masks, as a function of the position, and therefore is subject to less deposition. Ultimately, this produces fewer changes in the diffusely defined region (placed on gray background).

The defined, reproduced region 71″ therefore has a surface that is about 96% smaller than the mask openings 71′, 72′. The continuous deposition process results in the diffusely defined region placed on gray background in the surrounding area of the defined region 71″. Compared to a method where only one mask opening performing circular movements above the substrate (FIG. 6) is used, the surface of the diffusely defined region 71″ will advantageously be much smaller due to the overlapping region of the mask openings 71′ and 72′.

A configuration of at least two masks that are positioned one above the other and move relative to the substrate is therefore preferable, above one mask, provided that the diffuse region with temporary deposition is supposed to be reduced.

FIG. 8 shows the starting positions of a total of four mask openings 81′, 82′, 83′ and 84′ for producing a defined circular region 81″ and for forming the structure in or on a substrate. So as to form the circular structure in or on a substrate, the openings 81′, 82′, 83′ and 84′, either alone or in conjunction with the remaining mask openings, must reproduce a circle on the substrate through movements. The starting position of mask opening 81′ may be identical with the ending position of mask opening 82′. The ending position of mask opening 81′ may be identical with the starting position of mask opening 84′. The same principle applies to the remaining mask openings.

With their openings, the masks can then perform quarter-circle movements with a total of 7 positions (including the starting and ending positions) to define a circular region 81″, as is shown at the top right of FIG. 8. The sequence of movements of the mask openings 81′, 82′, 83′ and 84′ then either continues on the circular path or returns to the respective starting position. In the latter case, all masks perform quarter-circle movements, which only together with the remaining masks produce the circular, defined region 81″. The movements of the mask openings go back and forth, as is described for FIG. 7. In the first case, all masks perform circular movements themselves. The masks are moved above a substrate (not shown) that is placed in the image plane behind the openings 81′ and 82′, 83′ and 84′.

A deposition source may be provided in the image plane in front of the masks. Continuous deposition of the masks moving above the substrate defines the circular region 81″ on the inside of the mask openings 81′, 82′, 83′ and 84′ via the openings 81′, 82′, 83′ and 84′, which region is smaller than the respective surfaces of the openings 81′, 82′, 83′ and 84′ of the masks. This region 81″ is reproduced on the substrate. In the defined region 81″, the substrate clearly has a different structure than in the diffuse region covered partially with the masks. In other words, the defined region 81″ is subject to permanent deposition by the masks performing circular movements, while the region surrounding the defined region 81″ is covered mostly by the masks, as a function of the position, and therefore is subject to almost no change.

The defined, reproduced region 81″ therefore has a surface that is about 96% smaller than the mask openings 81′, 82′, 83′ and 84′. The continuous deposition process results in the diffusely defined regions placed on gray backgrounds in the immediate surrounding area of the defined region 81″. Compared to a method that uses only one or two mask openings performing circular movements above the substrate, as is shown in FIGS. 6 and 7, the surfaces of the diffusely defined, gray regions will be considerably smaller because, as a result of the overlapping region of the mask openings 81′, 82′, 83′ and 84′, the majority of the substrate remains covered during the circular movements of the masks by the solid regions of masks also during their movements. As has been shown above, very small diffuse regions are only produced at the four outer tips of the defined region 81″, which regions are placed on gray backgrounds in FIG. 8 at the bottom right.

The method according to the invention may also be performed completely without the movement of masks. For this purpose, at least two masks 91 and 92 with the openings 91′ and 92′ must be positioned axially one above the other and offset from each other in the X- and/or Y-directions above the substrate.

This way, the substrate, then the masks and thereon the structuring source, for example a deposition source, are positioned successively in the z-direction.

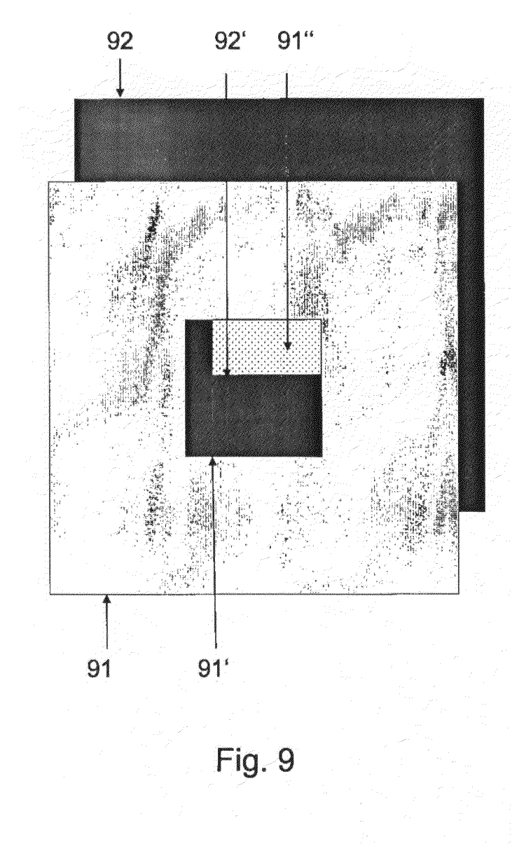

FIG. 9 shows such a configuration with square masks and square mask openings 91′, 92′. This way, the defined region 91″ is produced from continuous structuring, which region is shown with dos in FIG. 9 and has a rectangular shape. During the process, the reproduction of the mask openings on the substrate will also have smaller dimensions than the actual mask openings.

Depending on the offset of the masks 91, 92 in relation to each other in the X- and/or Y-directions, more or less small defined regions 91″ are produced in or on the substrate positioned in the image plane behind the masks through representation. This method offers the advantage that the masks and the substrate can be stationary.

It is conceivable to provide a plurality of openings in the two masks according to example 9 in an identical fashion. When offsetting the masks from each other in the X- and/or Y-direction, during continuous structuring, for example by means of deposition or exposure, a corresponding number of identical, smaller structures are produced than the mask openings in or on the substrate.

The offset of the masks in relation to each other in the X- and/or Y-positions can be maintained to move both masks with openings identically above the substrate following a deposition. During the movement, the deposition may be suspended to avoid diffuse regions. This way, the same structures are produced in or on the substrate, while keeping the mask configuration simple.

All possibilities mentioned in the illustrated embodiments for providing masks with defined openings, moving them in a geometrically defined fashion and performing a structuring step, for example a continuous or discontinuous deposition, in order to produce defined regions in or on the substrate, can be combined freely with each other.

The mask configurations are in no way limited to the illustrated embodiments. Rather, different openings are possible for a mask, which alone or in combination with further masks are held stationary or are moved so as to obtain structures, which are smaller than the structures limited in size by the mask opening and/or additionally have a different shape than the mask openings. Also the number of steps referred to above is only provided by way of example.

Instead of the masks, during the process the substrate or a layer provided on the substrate may be moved.

Defined regions of 1 nanometer, for example, can be produced quickly and with precision through the method. Depending on the mask opening, optical lithography, implantation or the deposition of materials (ions, metals and so on) may be carried out.

The speed of movement of the masks above the substrate will depend on the apparatus that is used for performing the method.

A nanomanipulator with piezoelectric element may perform the movements of the masks by selection in the kHz range, meaning in microseconds. Piezoelectric elements may be used to move the masks either directly or indirectly above microscope slides in which the masks are held. At least one piezoelectric element may be provided laterally on the mask or masks.

Through the discontinuous structuring and by repeating the sequence of movements of the masks, a different structure may be produced for the diffusely defined region (see also FIG. 2).

As has been shown according to FIGS. 5, 7, 8, 9 and 10, when a plurality of masks are used, the axial distance of the masks in relation to each other in the z-direction may be a few nanometers in the nanomanipulator.

The region defined in the illustrated embodiments may also be smaller or larger, depending on the sequence of movements of the mask. Specific overlaps may also be used to define structures that are larger than the mask.

Instead of deposition as the structuring method, implantation or optionally exposure may be used.

1. A method for structuring a substrate, according to which at least one mask with an opening is positioned above the substrate and unmasked regions are changed compared to masked regions of the substrate to form structures, a reproduction of the mask opening being produced on and/or in the substrate during the structuring process, which reproduction is smaller than the mask opening wherein the surface(s) of the mask opening(s) is (are) verified by appropriate means.

2. The method according to claim 1 wherein at least two masks with openings are positioned one above the other and offset from each other in the X- and Y-directions on the substrate.

3. The method according to claim 1 wherein at least one mask is moved in relation to the substrate during the method.

4. The method according to claim 1 wherein a structure is produced with the method on and/or in the substrate, which structure has a different geometric shape than the mask opening.

5. The method according to claim 1 wherein during the process a deposition, implantation or exposure step is carried out to produce the structure.

6. The method according to claim 1 wherein the geometry of the structure in the substrate is produced as a function of the geometry selected for the sequence of relative movements between the substrate and mask opening(s).

7. The method according to claim 1 wherein the structuring and/or the sequence of relative movements between the substrate and mask(s) are carried out discontinuously.

8. The method according to claim 1 wherein an inertial drive mechanism is used to perform the relative movements.

9. The method according to claim 1 wherein at least one mask is selected that comprises a glass carrier with a metal layer provided thereon.

10. The method according to claim 1 wherein at least one mask with a circular or square opening is selected.

11. The method according to claim 1 wherein a mask comprising magnetic material is selected.

12. The method according to claim 1, wherein at least one mask performs movements along a isosceles triangle or horizontal elliptic movements or a square movement or a circular movement or a semicircular movement.

13. The method according to claim 1 wherein the position(s) of the mask(s) relative to the substrate is (are) determined by optical, interferometric and/or capacitive sensors.

14. The method according to claim 1 wherein a diode arrangement is selected as the means for controlling the change of the mask opening surface.

15. An apparatus for carrying out the method according to claim 14, comprising at least two masks that are positioned one above the other on the substrate in the z-direction, the mask openings of which masks are offset from each other in the X- and/or Y-directions wherein the apparatus comprises means for controlling the change of the mask opening surface.

16. An apparatus for carrying out the method according to claim 14, the apparatus comprising means for performing relative movements between at least one mask with a mask opening and the substrate wherein the apparatus comprises means for controlling the change of the mask opening surface.

17. An apparatus for carrying out the method according to claim 15 that wherein the apparatus comprises means for performing relative movements between at least the masks with mask openings and the substrate.

18. The apparatus according to claims 15 characterized wherein the apparatus comprises micro- and/or nanoactuators as means for performing movements.

19. An apparatus according to claim 15 wherein the apparatus comprises at least one piezoelectric element as the means for performing movements.

20. An apparatus according to claim 15 characterized wherein the apparatus comprises at least one microscope slide that can move above the means for performing movements.

21. An apparatus according to claim 15 characterized wherein the apparatus comprises a microscope slide made of magnetic material.

22. An apparatus according to claim 15 wherein the means for performing movements are part of a nanomanipulator.

23. An apparatus according to claim 15 wherein this apparatus comprises a control unit for performing relative movements between the mask(s) and substrate in the nanometer range.

24. An apparatus according to claim 15 wherein this apparatus comprises a deposition or implantation source for structuring the substrate.

25. An apparatus according to claim 15 wherein this apparatus can perform discontinuous sequences of movements and/or structuring steps.

26. An apparatus according to claim 15 wherein at least one mask performs movements along an isosceles triangle or horizontal elliptic movements or square movements or circular movements or semicircular movements.

27. An apparatus according to claim 15 wherein the position(s) of the mask(s) relative to the substrate is (are) determined by optical, interferometric and/or capacitive sensors.

28. An apparatus according to claim 15 wherein this apparatus comprises a diode arrangement as the means for controlling the change of the mask opening surface.

29. The apparatus according to claim 28, wherein the diode arrangement is positioned beneath the mask openings.

30. An apparatus according to claim 28 wherein the diode arrangement can be used to direct a UV beam at the mask openings to control clogging of the masks.
